(19) United States
(12) Patent Application Publication
(10) Pub. No.: US 2006/0231026 A1
(43) Pub. Date: Oct. 19, 2006

(54) Vapor deposition systems having separate portions configured for purging using different materials

(76) Inventors: Moon-sook Lee, Seoul (KR); Byoung-jae Bae, Gyeonggi-do (KR)

Correspondence Address: MYERS BIGEL SIBLEY & SAJOVEC, PO BOX 37428, RALEIGH, NC, 27627, US

(21) Appl. No.: 11/453,412

(22) Filed: Jun. 15, 2006

Related U.S. Application Data
(62) Division of application No. 10/855,851, filed on May 27, 2004.

(30) Foreign Application Priority Data
Jul. 18, 2003 (KR) 10-2003-0049204

(51) Int. Cl. C23C 16/00

(52) U.S. Cl. 118/715

(57) ABSTRACT

A vapor deposition system can include a first portion of the vapor deposition system that is configured to be purged using a first material and a second portion that is configured to be purged using a second material. Related methods are also disclosed.

### CROSS-REFERENCE TO RELATED APPLICATIONS

This application is a divisional application of and claims priority to patent application Ser. No. 10/855,851, filed May 27, 2004 which claimed priority to Korean Patent Application No. 2003-0049204, filed on Jul. 18, 2003, in the Korean Intellectual Property Office, the content of which is incorporated herein by reference in its entirety.

### FIELD OF THE INVENTION

The invention relates to the fabrication of integrated circuits and, more particularly, to vapor deposition systems for the fabrication of integrated circuits and methods of operating the same.

### BACKGROUND

In general, a chemical vapor deposition (CVD) employs a reaction of gaseous chemicals to form a solid film on a substrate. In a typical CVD process, gaseous chemicals flow into a reaction chamber which form a film on a substrate, which is heated at a predetermined temperature.

It is known to use low pressure CVD (LPCVD) and atmosphere pressure CVD (APCVD). Commonly, the LPCVD is carried out in a low pressure environment at a high temperature to form a film having excellent step coverage and a high degree of purity. APCVD may be carried out in a high pressure environment at a relatively low temperature. APCVD may be characterized as having a fast deposition speed and enabling the use of a relatively simple reactor. APCVD may also form films having relatiely poor step coverage and a low degree of purity. It is also known to use plasma-enhanced CVD (PECVD) to form films, which may provide the advantages of a low depostion temperature, excellent step coverage and fast deposition speed.

It is also known to use atomic layer deposition (ALD) or a metal organic CVD (MOCVD) to address the issues discussed above in reference to LPCVD, APCVD, and PECVD. In ALD, a film having a thickness on the order of an atomic size can be formed on the substrate by means of injecting a source gas into the process chamber, which can be later removed from the reaction chamber. It is known that thickness uniformity and step coverage can be relatively good using ALD. MOCVD uses a polymer compound called a metal organic precursor, which is known to be useful in depositing specific metallic elements which otherwise may not be readily deposited using some other types of deposition processes in fabricating integrated circuit devices.

Referring to FIG. 1, a conventional vapor deposition system can include a reaction chamber 10 and a pump 60. The reaction chamber 10 includes an injection unit 11 connected to a first gas feed line 80 and a second gas feed line 82. A first reaction gas and a second reaction gas 23 are provided to the injection unit 11 through the first and second gas feed lines 80, 82, respectively. The first gas feed line 80 is connected to a vaporizer 50 to which a source material 20, a flushing material 40 and a carrier gas 30 are provided. To control a flow rate of the first reaction gas to the vaporizer 50, a mass flow controller (MFC) 25 is located between the source material 20 and the vaporizer, and a first feed valve 75 is located in-line with the first gas feed line 80.

During deposition, the source material 20 and the carrier gas 30 are evaporated in the vaporizer 50 and provided to the reaction chamber 10 through the first gas feed line 80. The source material 20 may be a metal organic precursor, and the first reaction gas may be the evaporated source material 20. The second reaction gas 23 reacts with the first reaction gas in the reaction chamber 10 to form a solid film on the wafer. The second reaction gas 23 may be a gas that is stable at room temperature and at atmospheric pressure, such as O₂ or N₂.

Because the first reaction gas may be re-liquefied at room temperature, a heating device is located in the first gas feed line 80 to prevent liquefaction of the first reaction gas. Re-liquefaction may occur in the vaporizer 50 during an idle time (e.g., when the wafer is shifting from the reaction chamber 10). Accordingly, during the idle time, the system may be purged to eliminate remnants of the source material 20 from the vaporizer 50. The purge step can include supplying a flushing material 40 to the vaporizer 50 and then exhausting the flushing material 40 from the system using the pump 60. The flushing material can be an organic material (e.g., a solvent). During the purge step, a source valve 25 (located in-line with a pipe connecting the source material 20 with the vaporizer 50) is closed to prevent the source material 20 from flowing into the vaporizer 50. It is not essential to carry out the purge step in the second gas feed line 82.

However, since the first and second reaction gases are supplied via separate gas lines, it may be difficult to adequately purify the line that provides the first reaction gas (i.e., feed gas line 80). In other words, during the purge step, if the first feed valve 75 is opened, materials remaining in the vaporizer 50 (i.e., the first reaction gas, the flushing material 40, and the carrier gas 30) may flow into the reaction chamber 10. As a result, the injection unit 11 and/or the reaction chamber 10 may be contaminated from the inflow of the flushing material 40 into the reaction chamber 10. In contrast, if the first feed valve 75 is closed during the purge step, the first gas feed line 80 and/or the injection unit 11 may be contaminated due to the accumulation of un-removed source material 20 therein.

In addition, if the flushing material 40 (or the source material 20) has a high degree of viscosity, the pump 60 may be overworked to maintain the low pressure environment in the reaction chamber for the LPCVD process.

### SUMMARY

Embodiments according to the invention can provide vapor deposition systems having separate portions configured for purging using different materials and methods of operating same. Pursuant to these embodiments, a vapor deposition system can include a first portion of the vapor deposition system configured to purge the first portion using a first material and a second portion of the vapor deposition system configured to purge the second portion using a second material.

Accordingly, the vapor deposition system can be separated into first and second portions where each of the portions can be purged with different materials. For example, the first portion may include the reaction chamber (and a portion of a gas feed line connected thereto) may be separable from the second portion that includes the vaporizer. The first portion can be purged using a non-solvent material (such as a carrier gas), whereas the second portion can be purged using a flushing material including a solvent. The reaction chamber may, therefore, be purged without contaminating the reaction chamber with a solvent material whereas the second portion may be purged using the solvent. Accordingly, during the interruption step for the flushing process, the source material remaining in the first gas feed line and the reaction chamber can be removed reliably. Thus, organic substances such as solvent do not flow into the reaction chamber.

In some embodiments according to the invention, the first material is a carrier gas and the second material comprises a flushing material, such as a flushing liquid. In some embodiments according to the invention, the first portion of the vapor deposition system is a gas exhaust line connected between a vaporizer and an exhaust pump. The second portion of the vapor deposition system is a gas feed line connected between a reaction chamber and a gas feed valve that are both downstream from the vaporizer.

In some embodiments according to the invention, the gas feed valve is configured to isolate the gas exhaust line from the gas feed line during a purge cycle of the vapor deposition system. In some embodiments according to the invention, the vapor deposition system includes a vaporizer and a reaction chamber downstream from the vaporizer in the vapor deposition system. A first gas feed line connects the vaporizer to the reaction chamber and a gas feed valve is in-line with the first gas feed line between the reaction chamber and the vaporizer. A second gas feed line is connected to the first gas feed line between the gas feed valve and the reaction chamber.

In some embodiments according to the invention, the vapor deposition system includes a vaporizer and a reaction chamber downstream from the vaporizer in the vapor deposition system. A first gas feed line connects the vaporizer to the reaction chamber and a gas feed valve is in-line with the first gas feed line between the reaction chamber and the vaporizer. A second gas feed line is connected to the first gas feed line between the gas feed valve and the reaction chamber. A carrier gas source is connected to the second gas feed line upstream from the reaction chamber. A reaction gas source is connected to the reaction chamber and a second feed valve connects the reaction gas source and carrier gas source.

In some embodiments according to the invention, the vapor deposition system includes a vaporizer and a reaction chamber downstream from the vaporizer in the vapor deposition system. A first gas feed line connects the vaporizer to the reaction chamber and a gas feed valve is in-line with the first gas feed line between the reaction chamber and the vaporizer. A second gas feed line is connected to the first gas feed line between the gas feed valve and the reaction chamber and a single carrier gas source is connected to the vaporizer and to the second gas feed line.

In some embodiments according to the invention, the vapor deposition system includes a reaction chamber and a vaporizer connected to the reaction chamber by a first gas feed line with a first feed valve. A pump is connected to the vaporizer by a gas exhaust line and a second gas feed line connects to the first gas feed line.

In some embodiments according to the invention, the vapor deposition system operates by purging a first portion of the vapor deposition system using a first material and purging a second portion of the vapor deposition system using a second material. In some embodiments according to the invention, the first material is a carrier gas and the second material is a flushing liquid.

### BRIEF DESCRIPTION OF THE DRAWINGS

FIG. 1 schematically shows a configuration of a conventional vapor deposition system.

FIG. 2 to 6 are block diagrams that illustrate some embodiments of vapor deposition systems according to the invention.

FIGS. 7 to 10 are cross-sectional views that illustrate some embodiments of injection units according to the invention.

FIG. 11 is a table that illustrates valve settings for operations of some embodiments of vapor deposition systems according to the invention.

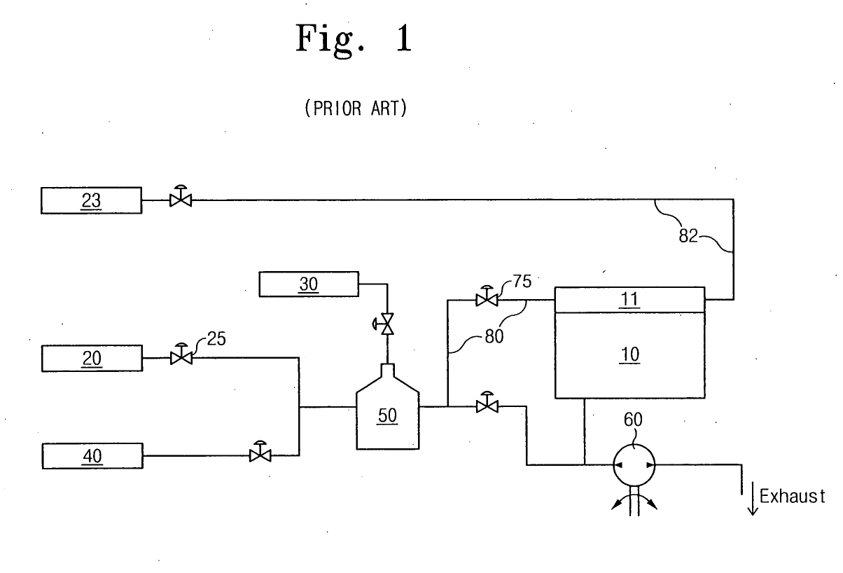

### DETAILED DESCRIPTION OF EMBODIMENTS ACCORDING TO THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a gas line is referred to as being “connected to” another element, it can be directly connected or intervening elements may also be present. the term “directly” means that there are no intervening elements. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. Thus, a first feed line could be termed a gas feed line, and, similarly, a second gas feed line could be termed a first gas feed line without departing from the teachings of the disclosure.

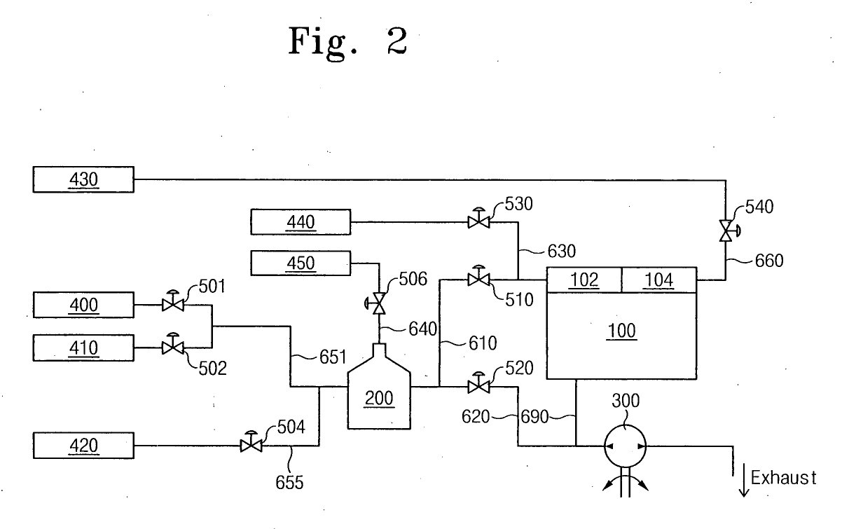

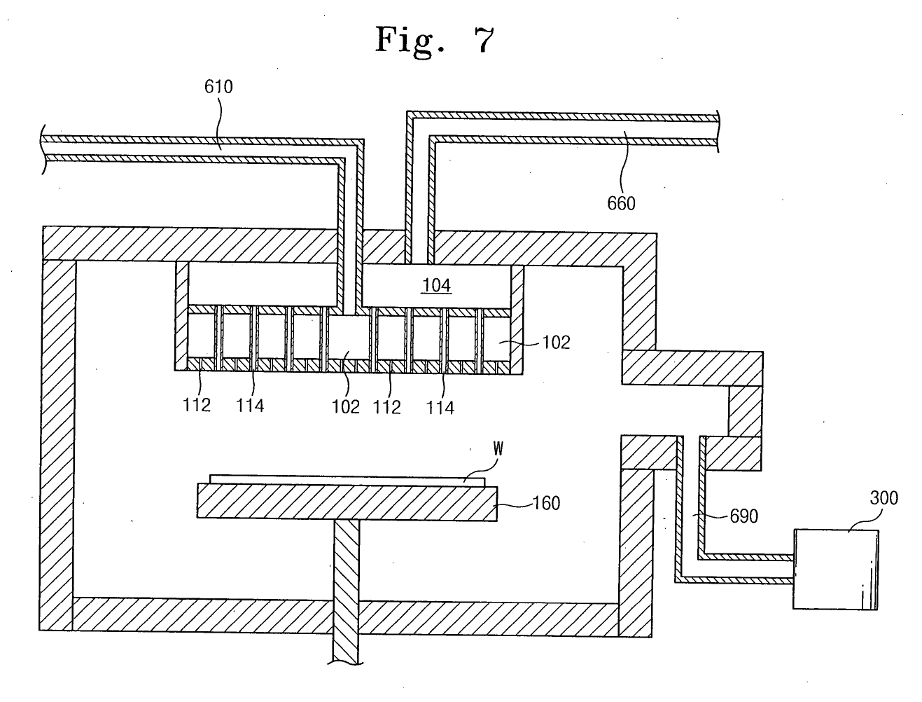

Referring to FIGS. 2 and 7, some embodiments of vapor deposition systems according to the invention include a reaction chamber 100, a vaporizer 200 and a pump 300. The reaction chamber 100 is connected to the vaporizer 200 by a first gas feed line 610 with a first feed valve 510 in-line therewith. The vaporizer 200 is connected to the pump 300 by a gas exhaust line 620 with an exhaust valve 520 in-line therewith. The system also includes a source material 400 (contained in a source material source), a reaction gas 430 (in a reaction gas source), a flushing material 420 (in a flushing material source), a first carrier gas 450 (in a first carrier gas source) and a second carrier gas 440 (in a second carrier gas source).

In some embodiments according to the invention, the source material 400 is a liquid-metal organic precursor. In some embodiments according to the invention, the reaction gas 430 is a gaseous chemical such as O₂, N₂ and N₂O etc. In some embodiments according to the invention, the flushing material 420 is a solvent, and the first and second carrier gases 450 and 440 are gases such as He, Ar and N₂. Other flushing materials and carrier gases can be used. In some embodiments according to the invention, the first gas feed line 610 and the gas exhaust line 620 are heated using, for example, a heating jacket that surrounds the first gas feed line 610 and the gas exhaust line 620.

The source material 400 is provided to the vaporizer 200 through a source line 651 with a source valve 501. The flushing material 420 is provided to the vaporizer 200 through a flushing line 655 with a flushing valve 504. The source line 651 is connected to the flushing line 655 upstream from the vaporizer 200. A second source material 410 is connected to the vaporizer 200 through the source line 651. A source valve 502 is located in-line with the source line 651 to control the supply of the second source material 410. It will be understood that additional source materials may be connected to the vaporizer 200. The first carrier gas 450 is provided to the vaporizer 200 through a carrier line 640 with a carrier valve 506.

It will be understood that the source line 651, the vaporizer 200, a portion of the first gas feed line 610 upstream from the first feed valve 510, and the gas exhaust line 620 are included in a first portion of the vapor deposition system according to some embodiments of the invention, which can be purged by a first material, such as, the flushing material 420. In particular, the first portion of the vapor deposition system can be isolated from other portions by closing the first feed valve 510.

A second feed line 630 having a second feed valve 530 is connected to the first gas feed line 610 between the first feed valve 510 and the reaction chamber 100 to provide the second carrier gases 440 into the reaction chamber 100. In some embodiments according to the invention, the first and second feed valves 510 and 530 are replaced by one 3-way valve. The 3-way valve can be set to provide either the material in the first gas feed line 610 or the second carrier gas 440 to the reaction chamber 100.

It will be understood that the second feed line 630, the portion of the first gas feed line 610 downstream from the first feed valve 510, and the reaction chamber 100 (include sub-components thereof) are included in a second portion of the vapor deposition system according to some embodiments of the invention that is separate from the first portion of the vapor deposition system. The second portion of the vapor deposition system can be purged by a second material, such as, the second carrier gas 440, which can be combined with the reaction gas in the reaction chamber 100. In particular, the second portion of the vapor deposition system can be isolated from the first portion by closing the first feed valve 510.

As shown in FIG. 7, the reaction chamber 100 includes an injection unit including a first injection part 102 and a second injection part 104 (i.e., a double shower head structure) which are separate from one another. The first injection part 102 is connected to the first gas feed line 610. Accordingly, the first injection part 102 may receive either the source material 400 (via the first gas feed line 610) or the second carrier gas 440 (via the second gas feed line 630). The second injection part 104 is connected to a reactant gas line 660 (having a reactant gas valve 540 in-line therewith) to receive the reactant gas 430. The first injection part 102 and the second injection part 104 include a first nozzle 112 and a second nozzle 114 respectively, which are located facing an upper plate of a susceptor, which is loaded with a substrate on which a film is deposited. The gases supplied through the first and second injection parts 102 and 104 are mixed after passing through the nozzles 112 and 114. The reaction chamber 100 is connected to the pump 300 by a reactant gas exhaust line 690.

During deposition of a film on the substrate, the source material 400 and the first carrier gases 450 are evaporated in the vaporizer 200 and supplied to the reaction chamber 100. At the same time, the reactant gases 430 are provided to the reaction chamber 100. Deposition is interrupted so that the system can be purged (or flushed), with the flushing material 420 and the first carrier gas 450 provided to the vaporizer 200, which are exhausted through the pump 300. During the purge of the system, the flow of source material 400 into the system is interrupted. Further, the first feed valve 510 is closed during the purge to avoid introducing the flushing material 420 into the reaction chamber 100.

During the purge of the system, the second carrier gas 440 flows into the reaction chamber 100 through the second gas feed line 630 connected between the first feed valve 510 and the reaction chamber 100. It will be understood that the second carrier gas 440 does not flow into the portion of the first gas feed line 610 that is upstream from the closed first feed valve 510. Therefore, it is possible that any source material remaining in the first gas feed line 610 (down stream from the closed first feed valve 510) and in the first injection part 102 may be purged without introducing the flushing material 420 into the reaction chamber, thereby reducing the likelihood of contamination.

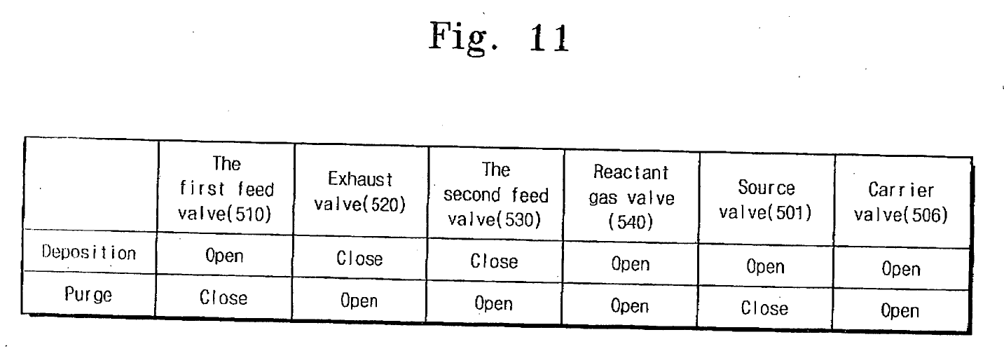

In relation to the supply/exhaust of the process gases, the system can be operated by a procedural scheme for opening and shutting valves, as shown in Table 1 in FIG. 11. In some embodiments according to the invention, the states of the valves (i.e., open/closed) included in the system are controlled by a programmable device. In some embodiments according to the invention, the programmable device can control operation of the pump 300 and the reaction chamber 100.

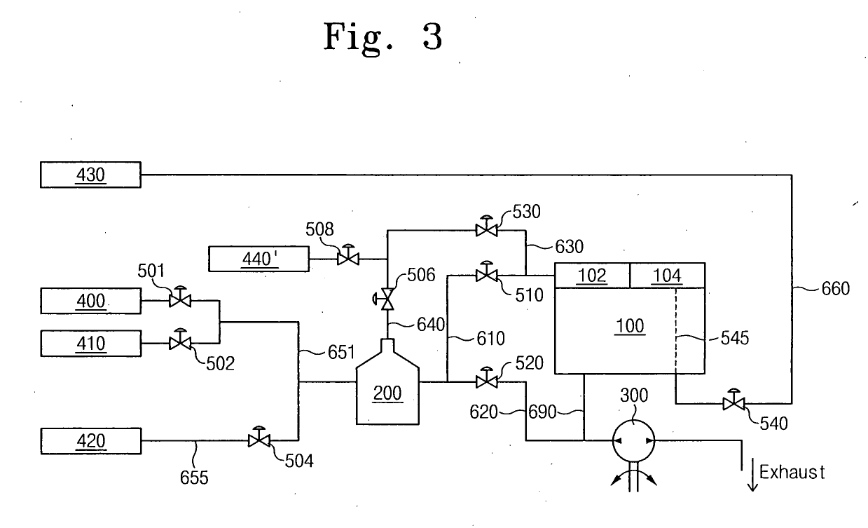

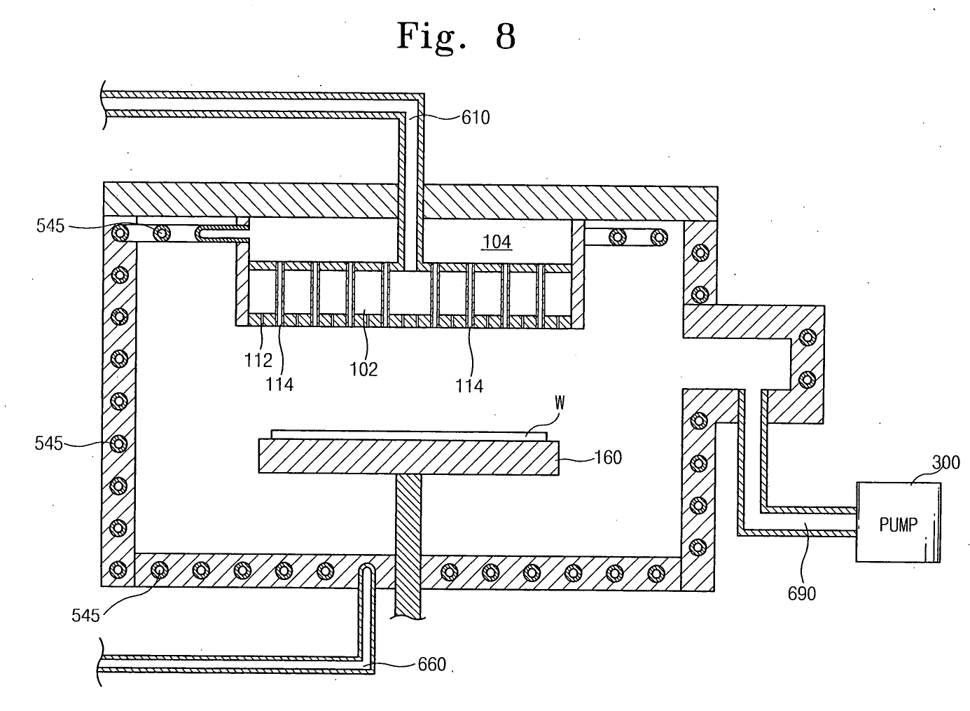

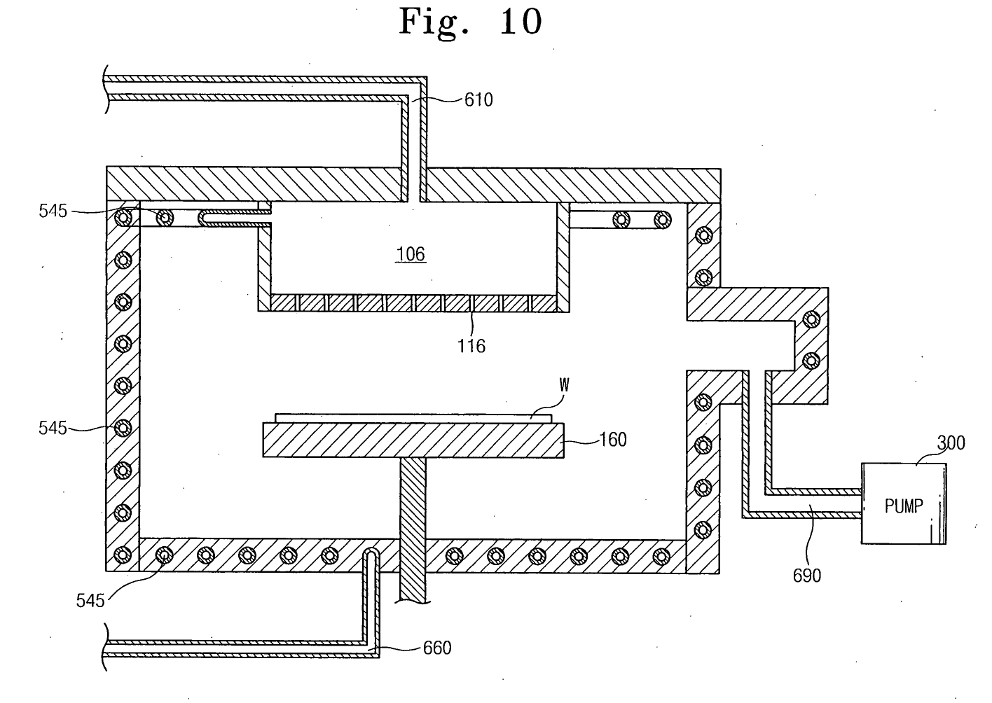

The embodiments according to the invention described above in reference to FIGS. 2 and 7 may be modified as shown in FIGS. 3 to 6 and FIGS. 7 to 10. Referring to FIGS. 3 and 8, the carrier line 640 and the second gas feed line 630 are both connected to a second carrier gases 440′ so that a common material may be used to purge the second portion of the vapor deposition system and to provide the carrier gas to the vaporizer 200 for combination, for example, with the source material 400. In other words, the second carrier gas 440′ may replace the first carrier gas 450 shown in FIG. 2. In addition, as shown in FIG. 8, the second injection part 104 may include a pipe line 545 and a shower head. An outer sidewall of the reaction chamber 100 is surrounded with the pipe line 545. The shower head is placed at an upper portion of the reaction chamber 100 and connects to the pipe line 545.

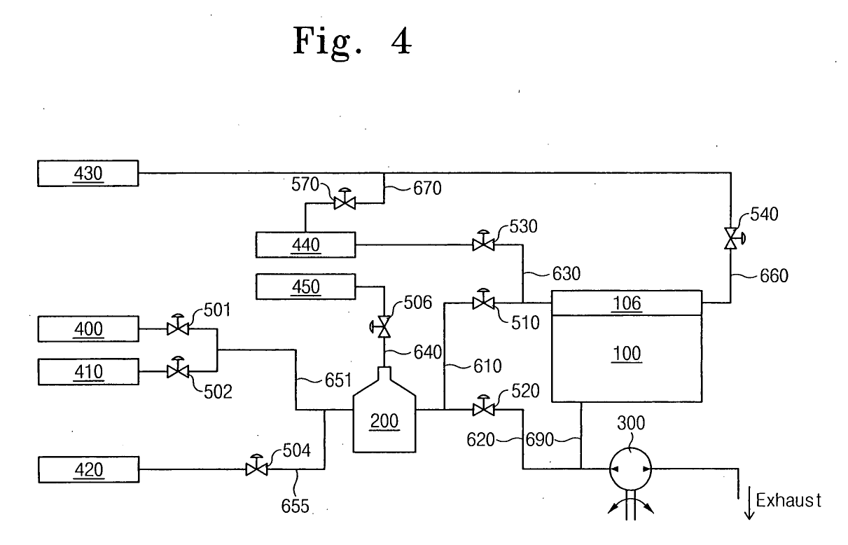

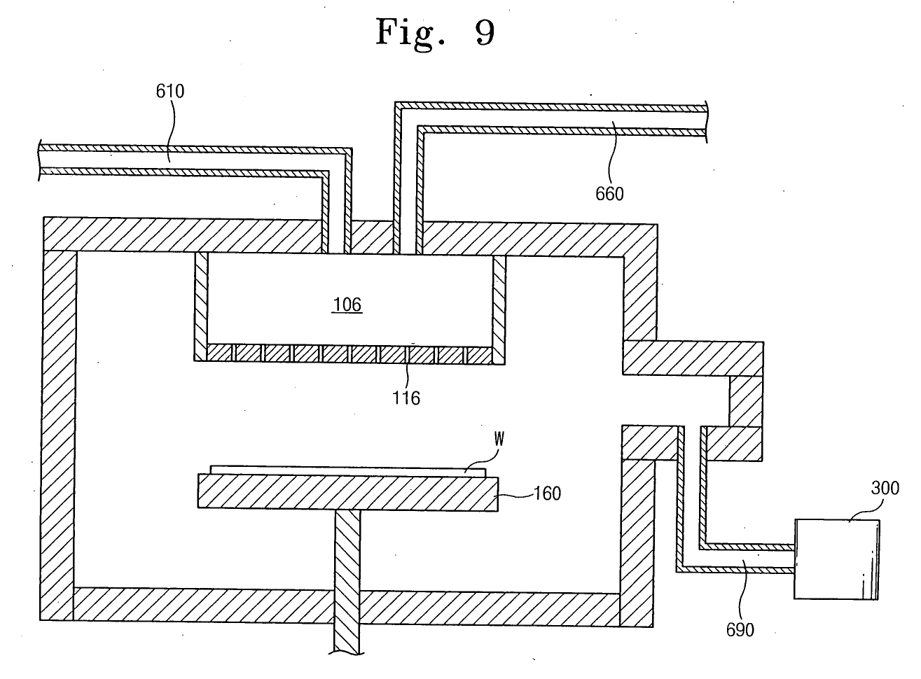

Furthermore, the injection unit (described in reference to FIG. 2) may be a single shower head 106 disposed at the upper portion of the reaction chamber 100, as shown in FIGS. 4 and 9. The single shower head 106 may have a plurality of injection nozzles 116 facing in the direction of the substrate. In some embodiments according to the invention, the materials introduced via the first gas feed line 610 and the materials introduced via the reactant gas line 660 mix in the single shower head 106.

Referring to FIG. 4, in some embodiments according to the invention, the reactant gas line 660 is connected to the second carrier gas 440 by a third carrier line 670 having a third carrier valve 570 in-line therewith. As a result, either the reactant gas 430 or the second carrier gas 440 can be supplied to the reaction chamber 100 selectively. Accordingly, during a purge of the system, the source material remaining in the single shower head 106 and in the reaction chamber 100 can be removed by the reactant gas 430 and/or the second carrier gas 440 provided via the reactant gas line 660. The source material remaining in the first gas feed line 610 downstream from the closed first feed valve 510 can be removed by the second carrier gases 440 that is supplied via the second gas feed line 630.

Furthermore, in some embodiments according to the invention, the system includes at least one source of a transport carrier gas (not shown) for transporting the source material 400, the flushing material 420 or the reactant gas 430 etc. As previously described in reference to FIG. 4, the third carrier valve 570 and the third carrier line 670 can be used to provide the carrier gas.

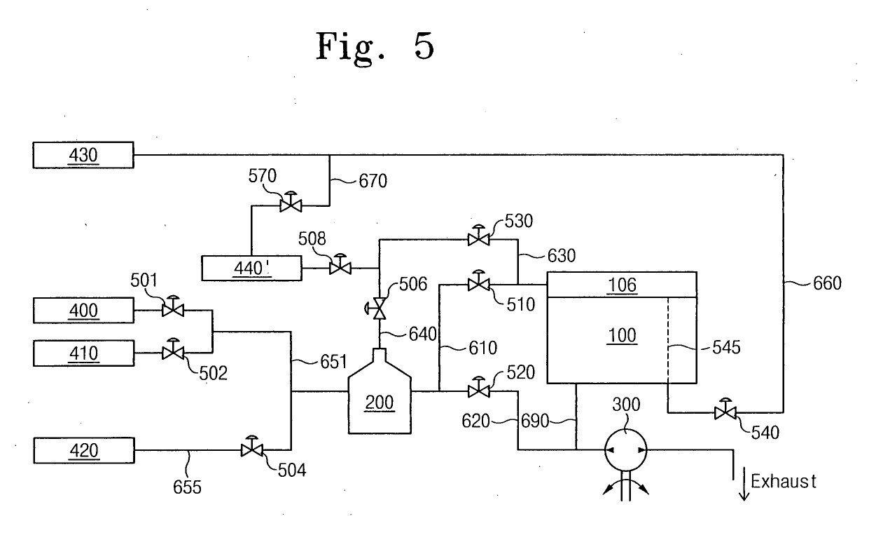

Referring to FIGS. 5 and 9, the third carrier line 670 having the third carrier valve 570 (described in reference to FIG. 4) is connected to the second carrier gas 440′ for common use (described in reference to FIG. 3). Accordingly, the second carrier gas 440′ is connected to the vaporizer 200 and, thereby, to the first carrier line 610. The injection unit includes a single shower head 106, as shown in FIG. 4.

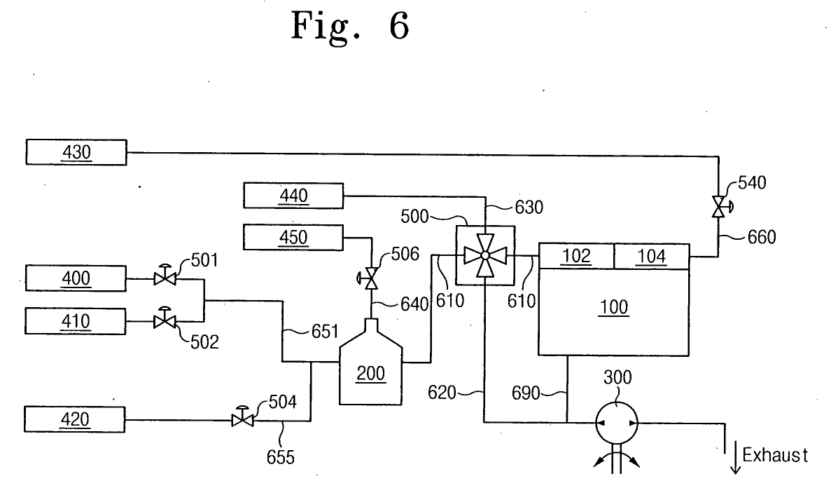

In some embodiments according to the invention, a 4-way valve 500, as shown in FIG. 6, can be used to connect the vaporizer 200, the reaction chamber 100, the pump 300 and the second carrier gas 440 to one another. Referring to FIG. 6, the 4-way valve 500 includes first and second terminals that are connected in-line with the first gas feed line 610 that connects the vaporizer 200 with the reaction chamber 100. The third and fourth terminals are connected in-line with the gas exhaust line 620 and the second gas feed line 630. It will be understood that the 4-way valve can replace the 2-way valve used in the other embodiments according to the invention, including those described herein.

According to the invention, the vapor deposition system can be separated into first and second portions where each of the portions can be purged with different materials. For example, the first portion may include the reaction chamber (and a portion of a gas feed line connected thereto), which may be separable from the second portion that includes the vaporizer. The first portion can be purged using a non-solvent material (such as a carrier gas), whereas the second portion can be purged using a flushing material including a solvent. The reaction chamber may, therefore, be purged without contaminating the reaction chamber with a solvent material whereas the second portion may be purged using the solvent. Accordingly, during the interruption step for the flushing process, the source material remaining in the first gas feed line and the reaction chamber can be removed reliably. Thus, organic substances such as solvent do not flow into the reaction chamber. As a result, the flushing process can be performed without contamination, and an overworking of the pump can be prevented.

Many alterations and modifications may be made by those having ordinary skill in the art, given the benefit of present disclosure, without departing from the spirit and scope of the invention. Therefore, it must be understood that the illustrated embodiments have been set forth only for the purposes of example, and that it should not be taken as limiting the invention as defined by the following claims. The following claims are, therefore, to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the invention.

What is claimed:

1. A vapor deposition system comprising:
a vaporizer;
a reaction chamber downstream from the vaporizer in the vapor deposition system;
a first gas feed line connecting the vaporizer to the reaction chamber;
a gas feed valve in-line with the first gas feed line between the reaction chamber and the vaporizer; and
a second gas feed line connected to the first gas feed line between the gas feed valve and the reaction chamber, the second gas feed line being connected to a carrier gas source upstream from the reaction chamber;
wherein the gas feed line further comprises a 4-way gas feed valve in-line with the first gas feed line between the reaction chamber and the vaporizer and in-line with the carrier gas source and an exhaust line connected to an exhaust pump.

2. A vapor deposition system comprising:
a vaporizer;
a reaction chamber downstream from the vaporizer in the vapor deposition system;
a first gas feed line connecting the vaporizer to the reaction chamber;
a gas feed valve in-line with the first gas feed line between the reaction chamber and the vaporizer;
a second gas feed line connected to the first gas feed line between the gas feed valve and the reaction chamber;
a carrier gas source connected to the second gas feed line upstream from the reaction chamber;
a reaction gas source connected to the reaction chamber; and
a second feed valve connecting the reaction gas source and carrier gas source.

3. A vapor deposition system according to claim 2 wherein the reaction chamber comprises:
a single shower head connected to the first gas feed line and to the reaction gas source.

4. A vapor deposition system comprising:
a vaporizer;
a reaction chamber downstream from the vaporizer in the vapor deposition system;
a first gas feed line connecting the vaporizer to the reaction chamber;
a gas feed valve in-line with the first gas feed line between the reaction chamber and the vaporizer;
a second gas feed line connected to the first gas feed line between the gas feed valve and the reaction chamber; and
a single carrier gas source connected to the vaporizer and to the second gas feed line.

5. A vapor deposition system according to claim 4 wherein the reaction chamber comprises:
a single shower head connected to the first gas feed line and to the reaction gas source.

6. A vapor deposition system comprising:
a reaction chamber;
a vaporizer connected to the reaction chamber by a first gas feed line with a 4-way valve having first, second, third and fourth terminals;
a pump connected to the vaporizer by a gas exhaust line; and
a second gas feed line connected to the first gas feed line;
wherein the first terminal is connected to the vaporizer by the first gas feed line, the second terminal is connected to the reaction chamber by the first gas feed line, the third terminal is connected to the pump by the gas exhaust line, and the fourth terminal is connected to the second feed line.
